(19) United States
(12) Patent Application Publication
(10) Pub. No.: US 2026/0235828 A1
(43) Pub. Date: Aug. 13, 2026

(54) Semiconductor Device and Method of Making a Rigid-Flex Co-Packaged Optics Module with Housing

(71) Applicant: STATS ChipPAC Management Pte. Ltd., Singapore (SG)

(72) Inventors: Gai Leong Lai, Singapore (SG); Heap Hoe Kuan, Singapore (SG)

(73) Assignee: STATS ChipPAC Management Pte. Ltd., Singapore (SG)

(21) Appl. No.: 19/049,317

(22) Filed: Feb. 10, 2025

(51) Int. Cl. G02B 6/42; G02B 6/43; H01L 21/56; H01L 23/31; H01L 23/367

(52) U.S. Cl. CPC G02B 6/4257; G02B 6/4269; G02B 6/43; H10W 40/22; H10W 74/016; H10W 74/117

(57) ABSTRACT

A semiconductor device has a flex cable. A substrate is attached to the flex cable. A first semiconductor die and photonic semiconductor die are disposed over the flex cable opposite the substrate. A housing is disposed on the flex cable over the first semiconductor die and photonic semiconductor die. A second semiconductor die is disposed over the substrate opposite the flex cable. An encapsulant is deposited over the second semiconductor die and substrate.

### FIELD OF THE INVENTION

The present invention relates in general to semiconductor devices and, more particularly, to semiconductor devices and methods of making rigid-flex co-packaged optics (CPO) modules with housing.

### BACKGROUND OF THE INVENTION

Semiconductor devices are commonly found in modern electronic products. Semiconductor devices perform a wide range of functions such as signal processing, high-speed calculations, transmitting and receiving electromagnetic signals, controlling electronic devices, transforming sunlight to electricity, and creating visual images for television displays. Semiconductor devices are found in the fields of communications, power conversion, networks, computers, entertainment, and consumer products. Semiconductor devices are also found in military applications, aviation, automotive, industrial controllers, and office equipment.

Photonic semiconductor devices, which are capable of transmitting or receiving signals via light, are becoming more and more common. Inter-device transmission via light has many advantages over electrical signals, particularly the avoidance of losses due to wire resistance and reduction of the impact of electromagnetic interference (EMI). However, the options for packaging photonic semiconductor devices have heretofore been limited and unsatisfactory in many ways. Therefore, a need exists for improved co-packaged optics (CPO) modules and methods of making them.

### BRIEF DESCRIPTION OF THE DRAWINGS

FIGS. 1a-1c illustrate a semiconductor wafer with a plurality of semiconductor die separated by a saw street;

FIGS. 2a-2j illustrate a process of forming a rigid-flex co-package optics module with the semiconductor die;

FIGS. 3a and 3b illustrate a first housing embodiment;

FIGS. 4a and 4b illustrate a second housing embodiment;

FIGS. 5a and 5b illustrate additional electrical interconnect options; and

FIGS. 6a and 6b illustrate an electronic device with the co-packaged optics module.

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings. The features shown in the figures are not necessarily drawn to scale. Elements assigned the same reference number in the figures have a similar function to each other. The term “semiconductor die” as used herein refers to both the singular and plural form of the words, and accordingly, can refer to both a single semiconductor device and multiple semiconductor devices.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, and resistors, create a relationship between voltage and current necessary to perform electrical circuit functions.

Back-end manufacturing refers to cutting or singulating the finished wafer into the individual semiconductor die and packaging the semiconductor die for structural support, electrical interconnect, and environmental isolation. To singulate the semiconductor die, the wafer is scored and broken along non-functional regions of the wafer called saw streets or scribes. The wafer is singulated using a laser cutting tool or saw blade. After singulation, the individual semiconductor die are disposed on a package substrate that includes pins or contact pads for interconnection with other system components. Contact pads formed over the semiconductor die are then connected to contact pads within the package. The electrical connections can be made with conductive layers, bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

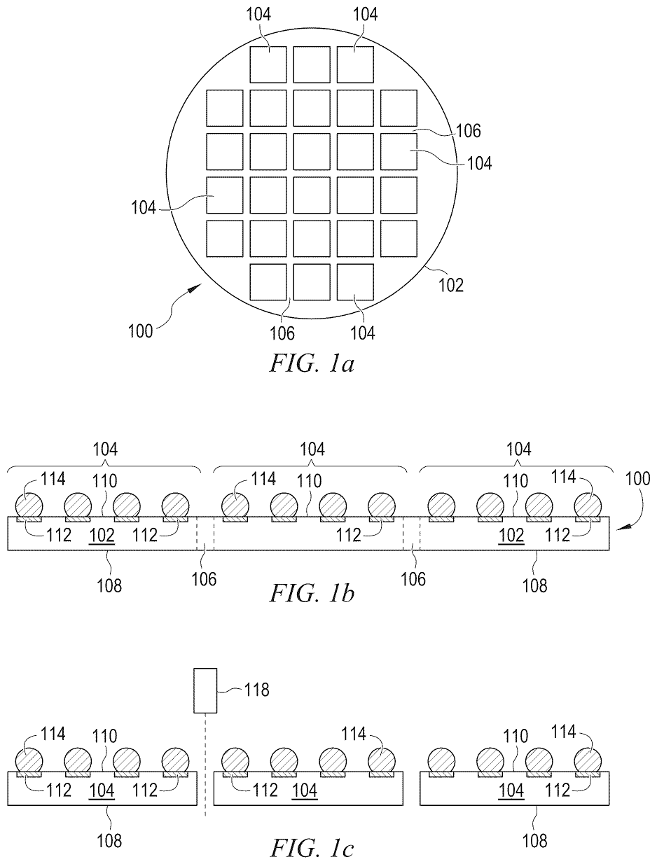

FIG. 1a shows a semiconductor wafer 100 with a base substrate material 102, such as silicon, germanium, aluminum phosphide, aluminum arsenide, gallium arsenide, gallium nitride, indium phosphide, silicon carbide, silicon nitride, lithium niobate (LiNbO3), or other bulk material for structural support. A plurality of semiconductor die or electrical components 104 is formed on wafer 100 separated by a non-active, inter-die wafer area or saw street 106. Saw street 106 provides cutting areas to singulate semiconductor wafer 100 into individual semiconductor die 104. In one embodiment, semiconductor wafer 100 has a width or diameter of 100-450 millimeters (mm).

FIG. 1b shows a cross-sectional view of a portion of semiconductor wafer 100. Each semiconductor die 104 has a back or non-active surface 108 and an active surface 110 containing analog or digital circuits implemented as active devices, passive devices, conductive layers, and dielectric layers formed over or within the die and electrically interconnected according to the electrical design and function of the die. For example, the circuit may include one or more transistors, diodes, and other circuit elements formed within active surface 110 to implement analog circuits or digital circuits, such as digital signal processor (DSP), application specific integrated circuits (ASIC), memory, power devices, or other signal processing circuit. Semiconductor die 104 may also contain IPDs, such as inductors, capacitors, and resistors, for RF signal processing.

An electrically conductive layer 112 is formed over active surface 110 using physical vapor deposition (PVD), chemical vapor deposition (CVD), electrolytic plating, electroless plating process, or other suitable metal deposition process. Conductive layer 112 can be one or more layers of aluminum (Al), copper (Cu), tin (Sn), nickel (Ni), gold (Au), silver (Ag), or other suitable electrically conductive material. Conductive layer 112 operates as contact pads electrically connected to the circuits on active surface 110.

An electrically conductive bump material is deposited over conductive layer 112 using an evaporation, electrolytic plating, electroless plating, ball drop, or screen printing process. The bump material can be Al, Sn, Ni, Au, Ag, lead (Pb), bismuth (Bi), Cu, solder, and combinations thereof, with an optional flux solution. For example, the bump material can be eutectic Sn/Pb, high-lead solder, or lead-free solder. The bump material is bonded to conductive layer 112 using a suitable attachment or bonding process. In one embodiment, the bump material is reflowed by heating the material above its melting point to form balls or bumps 114. In one embodiment, bump 114 is formed over an under-bump metallization (UBM) having a wetting layer, barrier layer, and adhesion layer. Bump 114 can also be compression bonded or thermocompression bonded to conductive layer 112. Bump 114 represents one type of interconnect structure that can be formed over conductive layer 112. The interconnect structure can also use bond wires, conductive paste, stud bump, micro bump, or other electrical interconnect.

In FIG. 1c, semiconductor wafer 100 is singulated through saw street 106 using a saw blade or laser cutting tool 118 into individual semiconductor die 104. The individual semiconductor die 104 can be inspected and electrically tested for identification of known good die (KGD) or known good unit (KGU) after singulation.

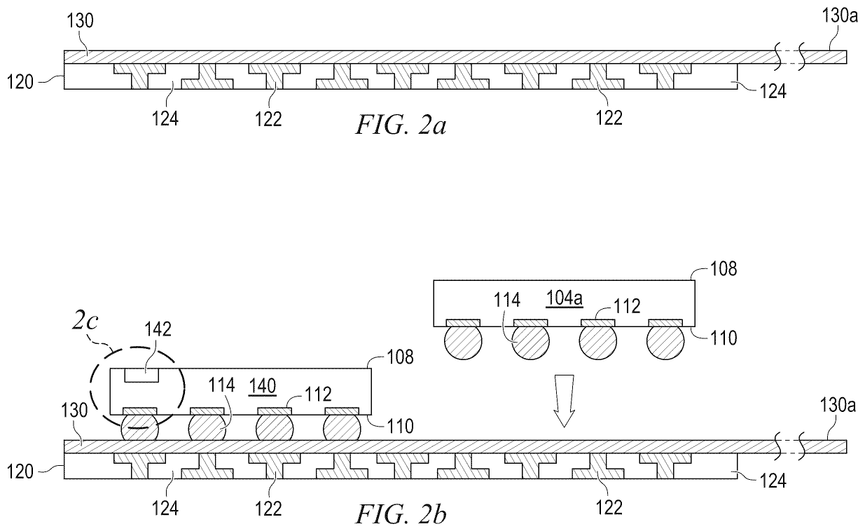

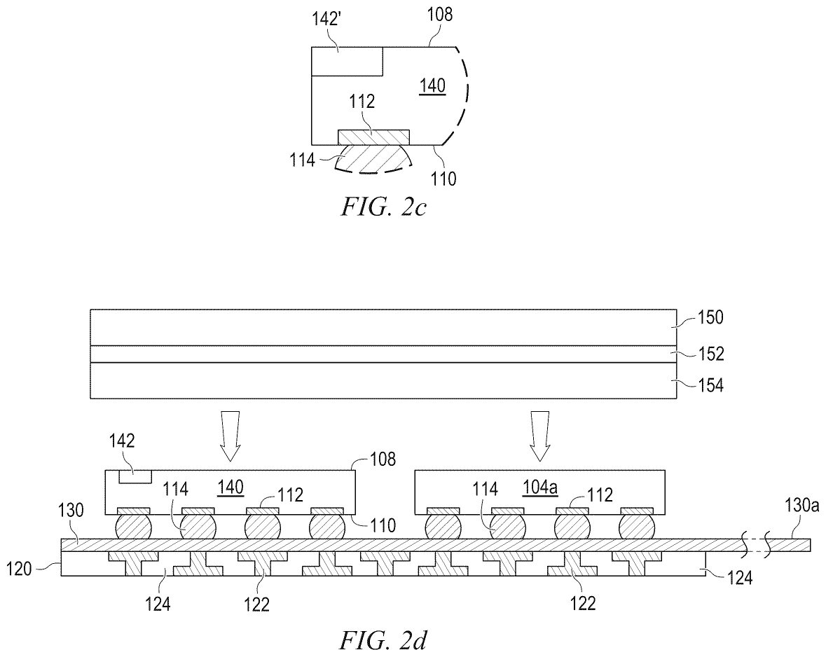

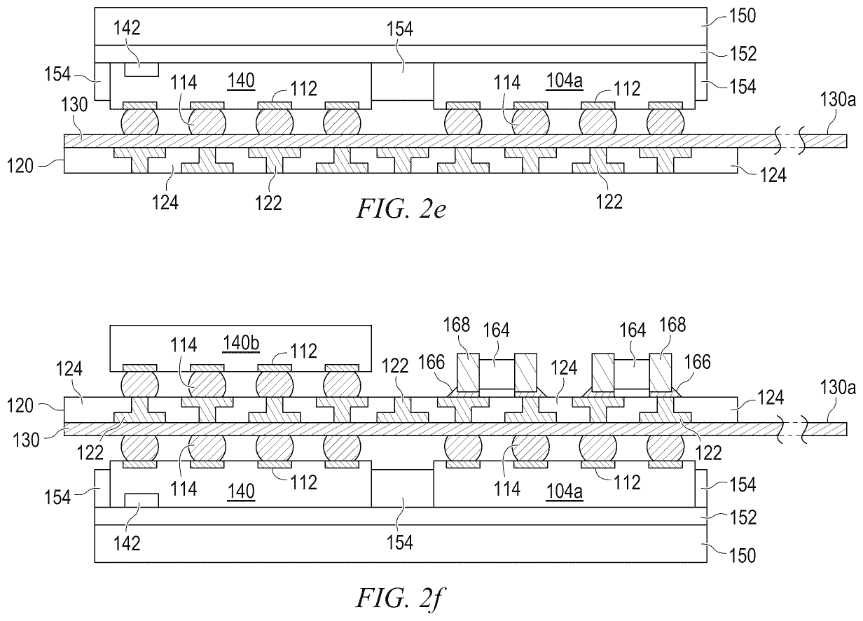

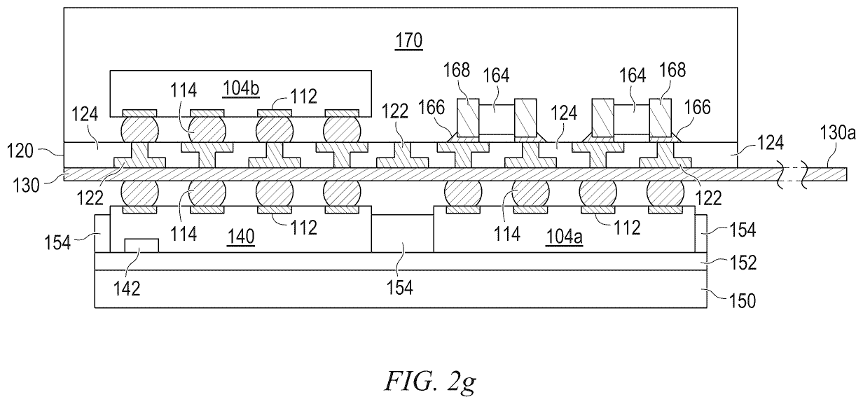

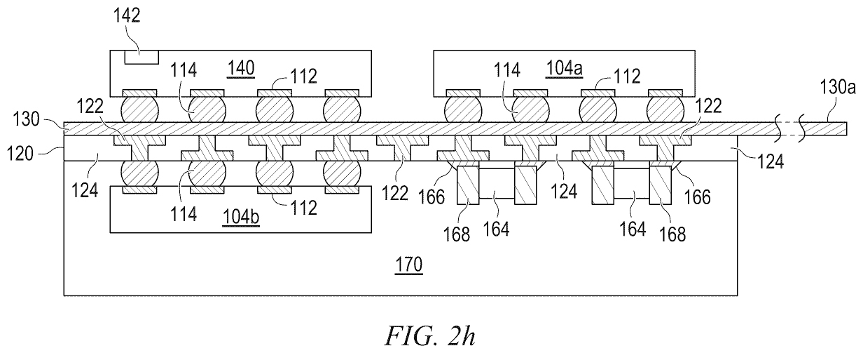

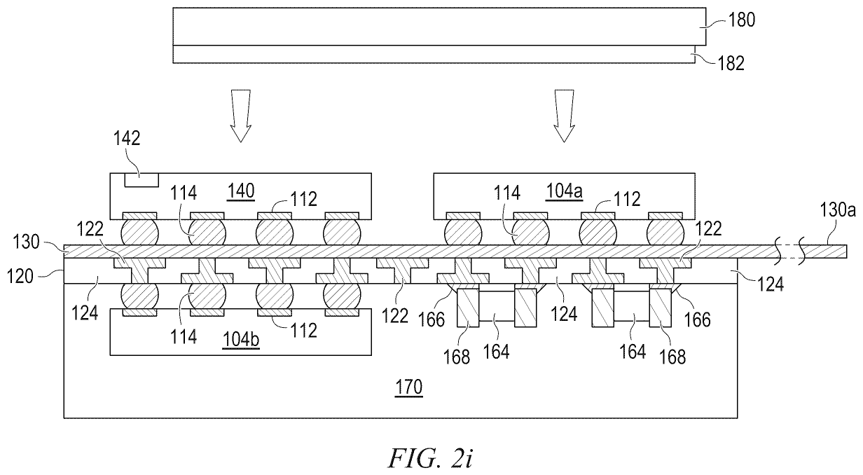

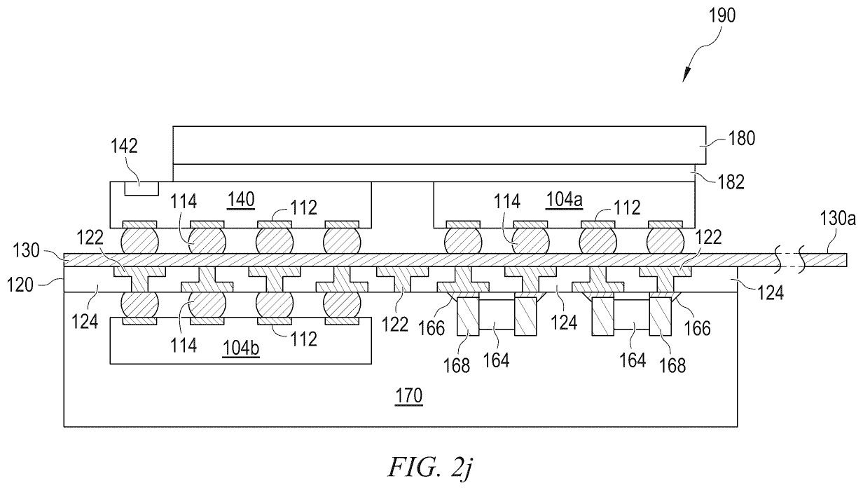

FIGS. 2a-2j illustrate the formation of a rigid-flex co-package optics module with semiconductor die 104. FIG. 2a shows a substrate 120. Substrate 120 is a multi-layered interconnect substrate including conductive layers 122 and insulating layers 124. Conductive layers 122 can be one or more layers of Al, Cu, Sn, Ni, Au, Ag, or other suitable electrically conductive material. Conductive layers 122 can be formed using PVD, CVD, electrolytic plating, electroless plating, or other suitable metal deposition process. Conductive layers 122 provide horizontal electrical interconnect across substrate 120 and vertical electrical interconnect between top and bottom surfaces. Portions of conductive layers 122 can be electrically common or electrically isolated depending on the design and function of the package or module being formed.

Insulating layers 124 contain one or more layers of SiO2, Si3N4, SiON, Ta2O5, Al2O3, solder resist, PI, BCB, PBO, and other material having similar insulating and structural properties. Insulating layers 124 can be formed using PVD, CVD, printing, lamination, spin coating, spray coating, sintering, thermal oxidation, or another suitable process. Insulating layers 124 provide isolation between conductive layers 122. Any number of conductive layers 122 and insulating layers 124 can be interleaved over each other to form substrate 120.

Any other suitable type of package substrate or leadframe is used for substrate 120 in other embodiments. For example, substrate 120 can be a laminate interposer, PCB, wafer-form, strip interposer, leadframe, or another suitable substrate. Substrate 120 may include one or more laminated layers of polytetrafluoroethylene pre-impregnated (prepreg), FR-4, FR-1, CEM-1, or CEM-3 with a combination of phenolic cotton paper, epoxy, resin, woven glass, matte glass, polyester, and other reinforcement fibers or fabrics.

Substrate 120 is formed on or attached to a flex cable 130. Flex cable 130 is a flexible cable with a plurality of conductive traces extending in parallel within an insulating film. Flex cable 130 can be a ribbon cable, flexible flat cable (FFC), flexible printed circuit (FPC), or another similar device. The insulating film can be polyimide, polyester, or another suitable insulating material, such as those mentioned above for insulating layer 124. The internal conductors can be copper, steel, aluminum, gold, or another suitable conductive material. Flex cable 130 is flexible, allowing the flex cable to bend and electrically connect to a connector that does not perfectly align to substrate 120. End 130a of flex cable 130 has exposed contacts that a connector will be electrically connected to when the end of the flex cable is inserted into the connector. In other embodiments, a board-to-board or other type of connector is mounted or soldered onto end 130a for interfacing with a compatible connector on another PCB.

The conductors of flex cable 130 can be screen printed onto an insulating film or patterned using photolithography. The patterned conductors can be laminated between two insulating films with a thermosetting adhesive coating that is activated by the laminating process. Any suitable process can be used to form flex cable 130 as a flexible cable with internal conductors. Flex cable 130 can be attached to substrate 120 by solder or a conductive adhesive. In other embodiments, substrate 120 is formed directly on flex cable 130 by building up insulating layers 124 and conductive layers 122 directly onto the flex cable using thin film deposition techniques. Substrate 120 is considered to be attached to flex cable 130 even in embodiments where the substrate is formed directly on the flex cable.

The CPO module being formed is referred to as a rigid-flex package because flex cable 130 is held rigid in the area where substrate 120 is attached and remains flexible elsewhere. In one embodiment, flex cable 130 and substrate 120 have co-extensive footprints in plan view other than end 130a extending outside the footprint of substrate 120 for subsequent electrical interconnect. Either substrate 120 or flex cable 130 can have portions that extend outside the footprint of the other at any given area of the device.

In FIG. 2b, a normal electronic semiconductor die 104a and a photonic semiconductor die 140 are disposed over and mounted to flex cable 130. Semiconductor die 104a is a semiconductor die 104 from FIG. 1c, or another semiconductor die formed and functioning similarly. Photonic semiconductor die 140 is formed in a similar manner to semiconductor die 104 in FIGS. 1a-1c, with the addition of being manufactured with an optically sensitive or photonic region 142 on back surface 108. Photonic region 142 is formed of a material capable of, or otherwise configured to, convert external optical or light signals received at the photonic region to electrical signals within photonic semiconductor die 140 that can then be processed by circuits of active surface 110 or back surface 108.

The reference numbers 104, 104a, and 104b refer to semiconductor die with purely electronic functionality. The reference number 140 refers to semiconductor die with photonic functionality. While two normal semiconductor die 104 and a single photonic semiconductor die 140 are shown in the illustrated embodiments, any number and combination of die can be used, including more than one photonic semiconductor die in a single package or module.

In some embodiments, photonic semiconductor die 140 is a photonic integrated circuit (PIC) containing photonic components that form a functioning circuit capable of detecting, generating, transporting or processing light. Semiconductor die 140 can be formed of indium phosphide (InP), which allows for the integration of various optically active and passive functions on the same chip. Photonic region 142 is configured to receive an optical signal into the photonic circuits of semiconductor die 140, either directly from the air or through an attached fiber-optic cable.

In some embodiments, photonic region 142 has a physical structure adapted to receive a fiber optic cable or signal, e.g., a grating coupler, and optionally has a separate connector mounted onto the surface of photonic semiconductor die 140. In other embodiments, semiconductor die 140 is configured to emit light from photonic region 142. Semiconductor die 140 may have multiple photonic regions 142, e.g., one or more for receiving optical signals and one or more for transmitting optical signals. A single photonic region 142 may also have multiple fiber optic cables coupled to the same region.

Photonic region 142 can be formed offset from an edge of photonic semiconductor die 140 as illustrated, in which case the CPO module being formed will be appropriate for use with a vertical fiber optic coupler. In other embodiments, such as illustrated in FIG. 2c as an alternative to the configuration shown in FIG. 2b, photonic region 142 can be formed at the edge of photonic semiconductor die 140. Having photonic region 142′ at the edge of photonic semiconductor die 140 makes the CPO module more appropriate for use with an edge coupler.

Both semiconductor die 140 and 104a are picked and placed over flex cable 130 with solder bumps 114 oriented toward the flex cable. Solder bumps 114 are aligned to exposed contact pads of flex cable 130. Solder bumps 114 are reflowed to physically and electrically connect semiconductor die 140 and 104a to the conductive traces embedded in flex cable 130. An underfill is optionally used under semiconductor die 104a and 140 to physically support the solder connections.

In FIG. 2d, a temporary carrier or stiffener 150 is disposed onto surfaces 108 of semiconductor die 104a and 140 with an adhesive or debonding layer 152 used to attach the stiffener to the die. Carrier 150 can be any suitable material, e.g., glass, metal, semiconductor, or polymer. Adhesive layer 162 is a thermal, UV, or other type of releasable adhesive or double-sided tape allowing carrier 150 to later be removed.

A temporary protection layer 154 is formed over carrier 150 and debonding layer 152. When carrier 150 is mounted onto semiconductor die 104a and 140 in FIG. 2e, the tops of the semiconductor die embed into protection layer 154. Protection layer 154 completely covers any exposed surfaces of photonic region 142 for protection during subsequent processing steps. Protection layer 154 can be any suitable mask, photoresist, epoxy, molding compound, or insulating material sufficient to protect photonic region 142.

In FIG. 2f, flex cable 130 is flipped so that substrate 120 is exposed for further processing. Semiconductor die 104b along with any other desired electrical components 164 are mounted onto substrate 120. Semiconductor die 104b is one of semiconductor die 104 from FIG. 1c, or another semiconductor die with different functionality but formed in a similar manner. Semiconductor die 104a and 104b can be the same or have complementary functionality, e.g., one might be a processor while the second is a memory chip. Semiconductor die 104a, 104b, and 140 are electrically coupled to each other through flex cable 130 and substrate 120.

Electrical components 164 can be discrete active or passive electrical devices, such as a diode, transistor, resistor, capacitor, or inductor. Electrical components 164 can include additional semiconductor die, semiconductor packages, surface mount devices, RF components, discrete active or passive electrical devices, and may include integrated passive devices (IPDs). Components 164 are electrically and physically coupled to substrate 120 by reflowing solder paste 166 between terminals 168 and contact pads of conductive layer 124 while solder bumps 114 are reflowed to attach semiconductor die 104b. An underfill is optionally used under any of the mounted components as desired.

In FIG. 2g, an encapsulant or molding compound 170 is deposited over substrate 120, semiconductor die 104b, and electrical components 164. Encapsulant 170 is deposited using a paste printing, compression molding, transfer molding, liquid encapsulant molding, vacuum lamination, spin coating, or other suitable applicator. Encapsulant 170 can be liquid or granular polymer composite material, such as epoxy resin, epoxy acrylate, or another suitable polymer, with or without a filler. Encapsulant 170 is non-conductive, provides structural support, and environmentally protects the embedded electrical components from external elements and contaminants. Encapsulant 170 is deposited in a mold that keeps the encapsulant contained to just over substrate 120. End 130a of flex cable 130 is not covered in encapsulant 170 to allow the flex cable to continue to operate.

In FIG. 2h, carrier 150 is removed by releasing debonding layer 152. Protection layer 154 is removed when peeling off carrier 150, or by a separate step of washing, chemical etching, mechanical etching, physically pulling, laser ablation, or another suitable means.

In FIG. 2i, a heat spreader 180 is disposed over and placed down onto back surfaces 108 of semiconductor die 104a and 140. Heat spreader 180 is a block of solid material, such as steel, aluminum, copper, alloys thereof, or another thermally conductive material. Heat spreader 180 can be cut to shape from a sheet of material. A thermal interface material (TIM) 182 is disposed on a surface of heat spreader 180 oriented toward semiconductor die 104a and 140. TIM 182 can be any suitable type of thermal material, such as thermal paste, thermal adhesive, or a thermally conductive pad. A thermal adhesive can be used to adhere heat spreader 180 to semiconductor die 104a and 140 during subsequent manufacturing steps. Heat spreader 180 absorbs thermal energy generated by semiconductor die 104a and 140 and presents a smooth surface external to the package being formed. The external surface of heat spreader 180 can have a heatsink attached thereto if necessary to more efficiently dissipate the thermal energy to ambient air. TIM 182 improves thermal transfer between the semiconductor die and heat spreader 180.

In FIG. 2j, heat spreader 180 has been mounted onto the back surfaces 108 of semiconductor die 104a and 140 to complete CPO module 190. Photonic region 142 remains exposed from heat spreader 180. Heat spreader 180 is a rectangle in some embodiments and placed outside a footprint of photonic region 142. In other embodiments, heat spreader 180 can have a concavity in plan view in which photonic region 142 is located so that the heat spreader extends to the left edge of photonic semiconductor die 140 in other cross-sections. In one embodiment, heat spreader 180 has an internal opening to accommodate photonic region 142.

CPO module 190 is complete, having flex cable 130 available for external electrical interconnect and photonic region 142 available for external optical interconnect. CPO module 190 is referred to as a rigid-flex CPO module because flex cable 130 is combined with a rigid substrate 120. In some embodiments, CPO module 190 is formed as part of a panel or strip of units and singulated after mounting heat spreader 180. CPO module 190 has two normal electronic semiconductor die 104a and 104b co-packaged with an optical or photonic semiconductor die 140. End 130a of flex cable 130 extends out from substrate 120 for subsequent electrical interconnect to an external system. Heat spreader 180 assists in dissipating heat generated from the module to enhance the life span and reliability of CPO module 190.

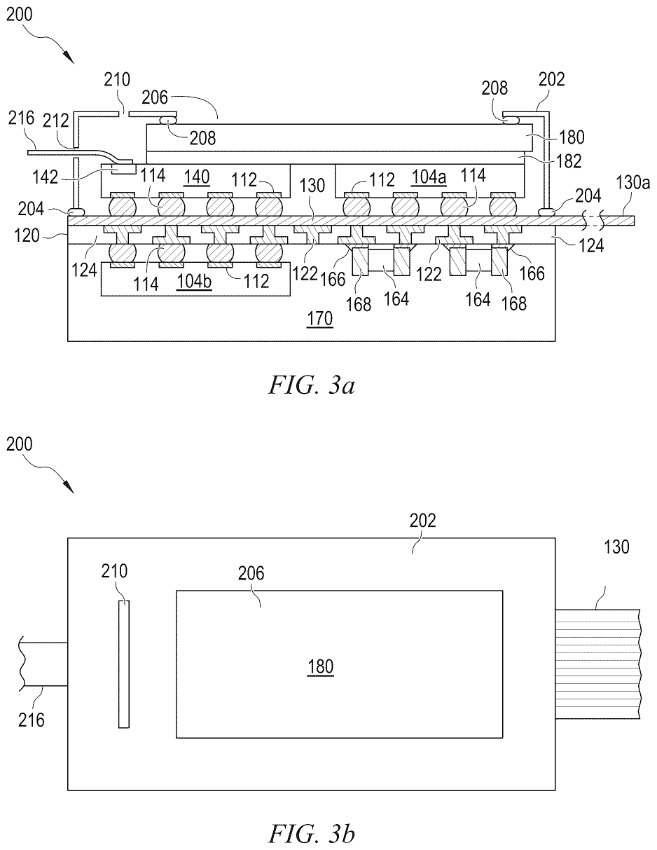

FIGS. 3a and 3b illustrate CPO module 200 having CPO module 190 from FIG. 2j with the addition of a housing, casing, or lid 202. FIG. 3a shows a cross-sectional view while FIG. 3b shows a plan view. Housing 202 is formed of a transparent or translucent material in some embodiments, e.g., glass or plastic. Housing 202 can be formed by injection molding or another suitable process. Housing 202 is picked and placed over semiconductor die 104a and 140 and then attached to flex cable 130 over substrate 120 using an adhesive 204.

Housing 202 has an opening 206 formed over heat spreader 180. Opening 206 is formed in the process of injection molding housing 202, or formed after molding by cutting, laser ablation, punching, or another suitable process. Opening 206 exposes heat spreader 180 to allow heat to dissipate away from CPO module 200, or for the subsequent attachment of a heat sink to the heat spreader. Opening 206 can be formed of any suitable size and shape but generally will be made as large as possible while leaving housing 202 overhanging the footprint of heat spreader 180 sufficiently to allow a bead of adhesive 208 to attach the housing to the heat spreader. Adhesive 208 can be the same adhesive and dispensed at the same time as adhesive 204.

Housing 202 includes openings or slots 210 and 212 configured for routing a fiber optic cable through the slots. Slot 210 is formed through the top of housing 202 above photonic region 142 for use with vertical couplers. Slot 212 is formed through a side of the housing adjacent to photonic region 142 for use with edge couplers. A fiber optic cable 216 is installed through slot 210 or 212, depending on which is more convenient for any given configuration, and either attached directly to photonic region 142 or to a coupler that was previously formed or mounted on the photonic region. Fiber optic cable 216 can be a single optical fiber or a plurality of parallel fibers bundled together and attached to photonic region 142 in parallel. Photonic region 142 can have a plurality of optical transmitters and/or receivers as desired.

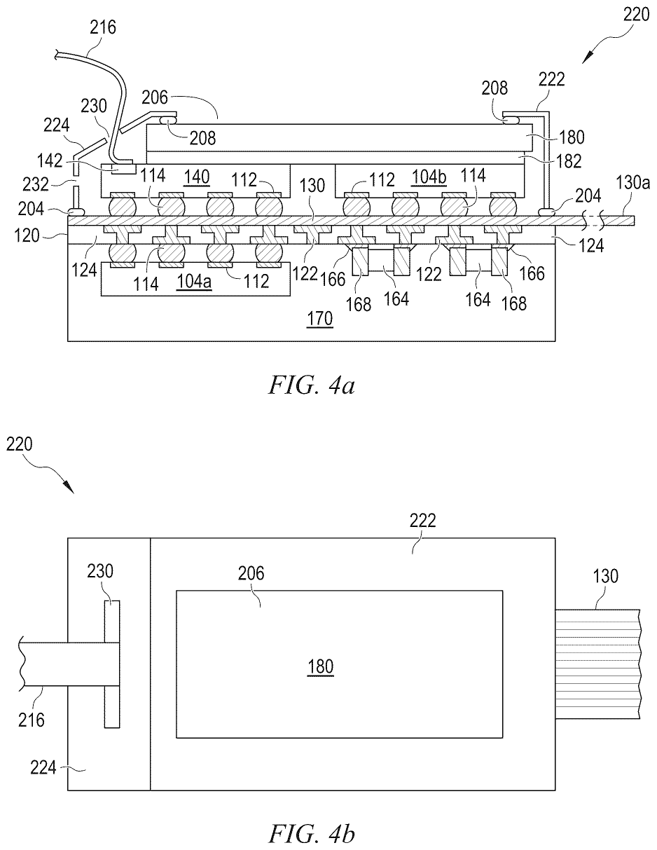

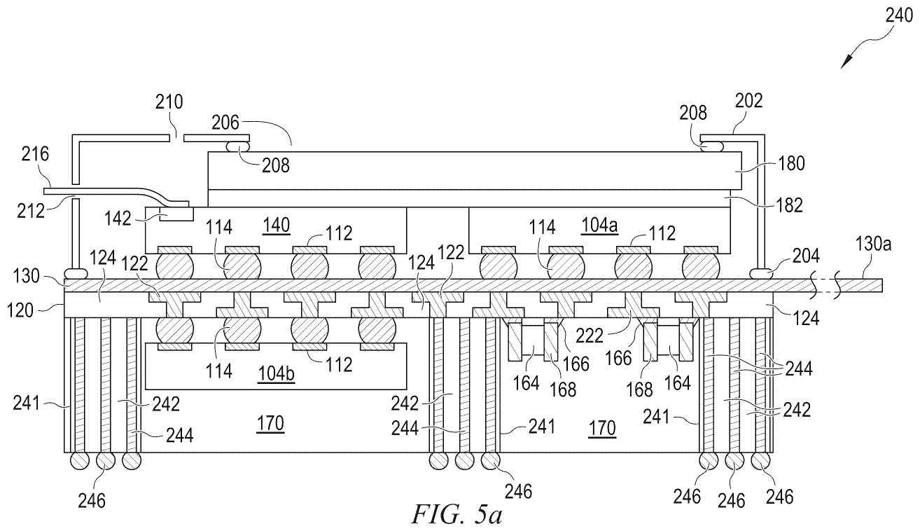

FIGS. 4a and 4b illustrate CPO module 220 having CPO module 190 from FIG. 2j with the addition of a housing, casing, or lid 222. FIG. 4a shows a cross-sectional view while FIG. 4b shows a plan view. Housing 222 is formed and operates similarly to housing 202. Relative to housing 202, housing 222 is modified by being chamfered due to sloped surface 224 over photonic region 142. Sloped surface 224 extends from the top to the side of housing 222. Opening or slot 230 is formed through sloped surface 224 and slot 232 is formed through the side of the housing. Slot 230 is generally used for vertical connectors while slot 232 is generally used for edge connectors, but either slot 230 or 232 can be used in any embodiment depending on which is more convenient in the particular use-case.

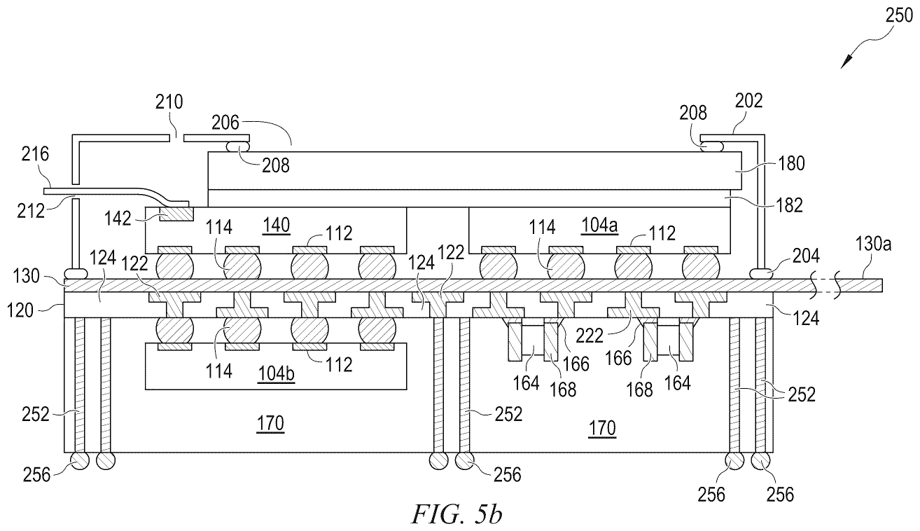

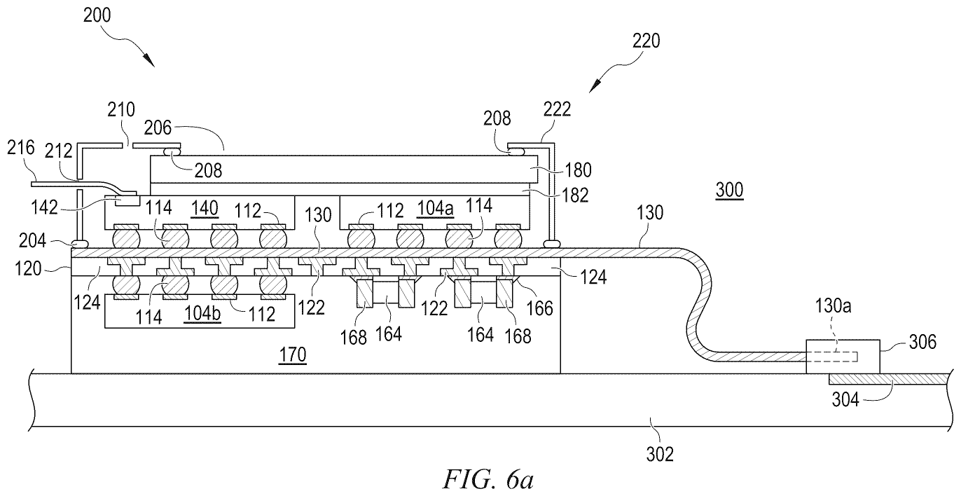

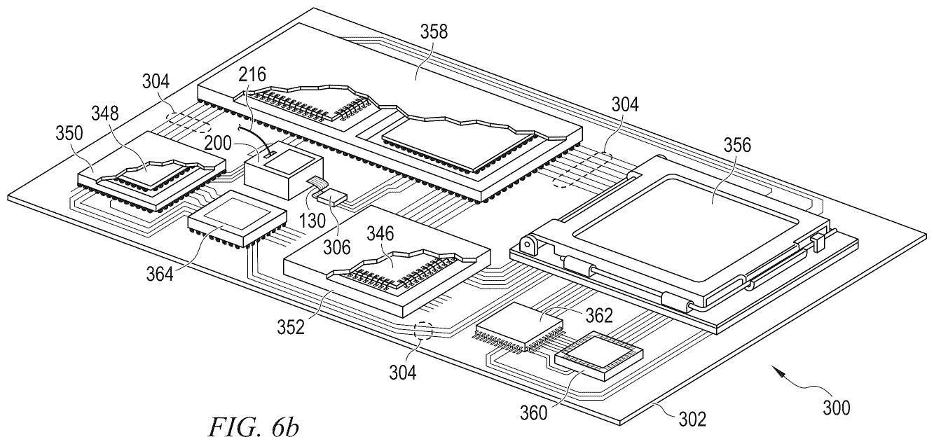

FIGS. 5a and 5b illustrate additional electrical interconnect options. In FIG. 5a, CPO module 240 has PCB units or e-Bars 241 that are disposed on substrate 120 during the step when semiconductor die 104b and components 164 are mounted in FIG. 2f. PCB units 241 can be picked and placed onto substrate 120 and coupled to conductive layer 122 using a thin layer of solder paste or any other suitable means. PCB units 241 include a base insulating material 242 and conductive vias 244 formed through the insulating material. Insulating material 242 can be any suitable material described above for encapsulant or insulating layers generally. PCB units 241 are pre-formed and then disposed on substrate 120. In one embodiment, PCB units 241 are built up as part of the process of forming substrate 120. In some embodiments, PCB units 241 include additional conductive layers, RDL, or contact pads formed over one or both ends of conductive vias 244. Encapsulant 170 is deposited over PCB units 241. Encapsulant 170 can be deposited coplanar to PCB units 241 or optionally backgrinded to expose the PCB units. Solder bumps 246 are formed on PCB units 241 as described above for solder bumps 114, typically at the end of the manufacturing process.

FIG. 5b shows CPO module 250 with conductive vias 252 formed through encapsulant 170. Conductive vias 252 can be pre-formed pillars disposed on substrate 120 prior to encapsulation, or conductive vias formed in holes drilled into encapsulant 170. The holes can be formed through encapsulant 170 to expose contact pads of conductive layer 122 using chemical etching, laser drilling, mechanical drilling, or any other suitable means. Any suitable conductive material is deposited into the openings using any suitable metal deposition technique. Solder bumps 256 are formed on conductive vias 252 as described above for solder bumps 114. In some embodiments, contact pads, under-bump metallization, conductive traces, or other conductive structures are formed on the surfaces of encapsulant 170 and conductive vias 252 prior to solder ball attach.

Conductive vias 252 and PCB units 241 are vertical interconnect structures to provide an alternative or supplemental electrical connection mechanism along with flex cable 130. CPO modules 240 and 250 can be mounted onto a PCB and electrically connected to that PCB through solder bumps 246 or 256, while flex cable 130 provides electrical connection to another PCB or to another package on the same PCB.

FIGS. 5a and 5b illustrate integrating the above-described semiconductor packages, e.g., CPO module 200, into a larger electronic device 300. FIG. 5a illustrates a partial cross-section of CPO module 172 mounted onto a printed circuit board (PCB) or other substrate 302 as part of electronic device 300. An adhesive or underfill layer is used to attach CPO module 200 to PCB 302. Flex cable 130 is routed so that end 130a of the flex cable extends into a connector 306. Connector 306 is soldered onto conductive layer 304 of PCB 302 and has internal electrical contacts that apply pressure against exposed contacts of flex cable 130 for electrical connection.

Semiconductor die 104a, 104b, and 140 are electrically coupled to conductive layer 304 through substrate 120, flex cable 130, and connector 306. Optical fiber 216 is attached to photonic region 142 to provide optical functionality to device 300. Photonic semiconductor die 140 is used by electronic device 300 to send or receive an optical signal via the optical fiber or perform any other suitable optical function. In another embodiment, photonic region 142 is left exposed to detect ambient light incident to CPO module 200.

FIG. 5b illustrates electronic device 300 having a chip carrier substrate or PCB 302 with a plurality of semiconductor packages disposed on a surface of PCB 302, including CPO module 200. Electronic device 300 can have one type of semiconductor package, or multiple types of semiconductor packages, depending on the application.

Electronic device 300 can be a stand-alone system that uses the semiconductor packages to perform one or more electrical functions. Alternatively, electronic device 300 can be a subcomponent of a larger system. For example, electronic device 300 can be part of a tablet, cellular phone, digital camera, communication system, or other electronic device. Alternatively, electronic device 300 can be a graphics card, network interface card, or other signal processing card that can be inserted into a computer. The semiconductor package can include microprocessors, memories, ASICs, logic circuits, analog circuits, RF circuits, discrete devices, or other semiconductor die or electrical components. Miniaturization and weight reduction are essential for the products to be accepted by the market. The distance between semiconductor devices may be decreased to achieve higher density. PCB 302 may have a more irregular shape to fit conveniently into more ergonomic and smaller device shells.

In FIG. 5b, PCB 302 provides a general substrate for structural support and electrical interconnect of the semiconductor packages disposed on the PCB. Conductive signal traces 304 are formed over a surface or within layers of PCB 302 using evaporation, electrolytic plating, electroless plating, screen printing, or other suitable metal deposition process. Signal traces 304 provide for electrical communication between each of the semiconductor packages, mounted components, and other external system components. Traces 304 also provide power and ground connections to each of the semiconductor packages.

In some embodiments, a semiconductor device has two packaging levels. First level packaging is a technique for mechanically and electrically attaching the semiconductor die to an intermediate substrate. Second level packaging involves mechanically and electrically attaching the intermediate substrate to the PCB. In other embodiments, a semiconductor device may only have the first level packaging where the die is mechanically and electrically disposed directly on the PCB.

For the purpose of illustration, several types of first level packaging, including bond wire package 346 and flipchip 348, are shown on PCB 302. Additionally, several types of second level packaging, including ball grid array (BGA) 350, bump chip carrier (BCC) 352, land grid array (LGA) 356, multi-chip module (MCM) or SIP module 358, quad flat non-leaded package (QFN) 360, quad flat package 362, and embedded wafer level ball grid array (eWLB) 364 are shown disposed on PCB 302. In one embodiment, eWLB 364 is a fan-out wafer level package (Fo-WLP) or a fan-in wafer level package (Fi-WLP).

Depending upon the system requirements, any combination of semiconductor packages, configured with any combination of first and second level packaging styles, as well as other electrical components, can be connected to PCB 302. In some embodiments, electronic device 300 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using less expensive components and a streamlined manufacturing process. The resulting devices are less likely to fail and less expensive to manufacture resulting in a lower cost for consumers.

While one or more embodiments of the present invention have been illustrated in detail, the skilled artisan will appreciate that modifications and adaptations to those embodiments may be made without departing from the scope of the present invention as set forth in the following claims.

What is claimed:

1. A method of making a semiconductor device, comprising:
providing a flex cable;
attaching a substrate to the flex cable;
disposing a first semiconductor die and a photonic semiconductor die over the flex cable opposite the substrate;
disposing a housing on the flex cable over the first semiconductor die and photonic semiconductor die;
disposing a second semiconductor die over the substrate opposite the flex cable; and
depositing an encapsulant over the second semiconductor die and substrate.

2. The method of claim 1, wherein the housing includes an opening over a photonic region of the photonic semiconductor die.

3. The method of claim 2, wherein the housing includes a sloped surface over the photonic region, and wherein the opening is formed in the sloped surface.

4. The method of claim 1, further including disposing a heat spreader over the first semiconductor die and photonic semiconductor die.

5. The method of claim 4, wherein the housing includes an opening over the heat spreader.

6. The method of claim 1, further including disposing a vertical interconnect structure over the substrate and extending through the encapsulant.

7. A method of making a semiconductor device, comprising:
providing a flex cable;
attaching a substrate to the flex cable;
disposing a photonic semiconductor die over the flex cable opposite the substrate; and
disposing a housing on the flex cable over the photonic semiconductor die.

8. The method of claim 7, wherein the housing includes an opening over a photonic region of the photonic semiconductor die.

9. The method of claim 8, wherein the housing includes a sloped surface over the photonic region, and wherein the opening is formed in the sloped surface.

10. The method of claim 7, further including disposing a heat spreader over the photonic semiconductor die.

11. The method of claim 10, wherein the housing includes an opening over the heat spreader.

12. The method of claim 7, further including:
disposing a semiconductor die over the substrate opposite the photonic semiconductor die;
depositing an encapsulant over the semiconductor die; and
disposing a vertical interconnect structure over the substrate and extending through the encapsulant.

13. The method of claim 7, further including:
extending a fiber optic cable through an opening of the housing; and
coupling the fiber optic cable to the photonic semiconductor die.

14. A semiconductor device, comprising:
a flex cable;
a substrate attached to the flex cable;
a first semiconductor die and a photonic semiconductor die disposed over the flex cable opposite the substrate;
a housing disposed on the flex cable over the first semiconductor die and photonic semiconductor die;
a second semiconductor die disposed over the substrate opposite the flex cable; and
an encapsulant deposited over the second semiconductor die and substrate.

15. The semiconductor device of claim 14, wherein the housing includes an opening over a photonic region of the photonic semiconductor die.

16. The semiconductor device of claim 15, wherein the housing includes a sloped surface over the photonic region, and wherein the opening is formed in the sloped surface.

17. The semiconductor device of claim 14, further including a heat spreader disposed over the first semiconductor die and photonic semiconductor die.

18. The semiconductor device of claim 17, wherein the housing includes an opening over the heat spreader.

19. The semiconductor device of claim 14, further including a vertical interconnect structure disposed over the substrate and extending through the encapsulant.

20. A semiconductor device, comprising:
a flex cable;
a substrate attached to the flex cable;
a photonic semiconductor die disposed over the flex cable opposite the substrate; and
a housing disposed on the flex cable over the photonic semiconductor die.

21. The semiconductor device of claim 20, wherein the housing includes an opening over a photonic region of the photonic semiconductor die.

22. The semiconductor device of claim 21, wherein the housing includes a sloped surface over the photonic region, and wherein the opening is formed in the sloped surface.

23. The semiconductor device of claim 20, further including a heat spreader disposed over the photonic semiconductor die.

24. The semiconductor device of claim 23, wherein the housing includes an opening over the heat spreader.

25. The semiconductor device of claim 20, further including a fiber optic cable extending through an opening of the housing.
